(19) United States
(12) Patent Application Publication
(10) Pub. No.: US 2005/0233613 A1
(43) Pub. Date: Oct. 20, 2005

(54) Coupling structure of electronic components

(76) Inventors: Katsuyuki Naitoh, Hiroshima (JP); Kenji Toyosawa, Hiroshima (JP)

Correspondence Address: BIRCH STEWART KOLASCH & BIRCH, PO BOX 747, FALLS CHURCH, VA, 22040-0747, US

(21) Appl. No.: 11/107,924

(22) Filed: Apr. 18, 2005

(30) Foreign Application Priority Data
Apr. 19, 2004 (JP) 2004-123133

(51) Int. Cl. H01R 12/00; H05K 1/00

(52) U.S. Cl. 439/67

(57) ABSTRACT

A coupling structure of electronic components, by which the break down of drive wiring at the time of folding a flexible substrate is prevented and the reliability of wiring is increased, is realized. In the coupling structure of electronic components of the present invention, a liquid crystal driver and a liquid crystal panel are arranged such that a surface of the flexible substrate, that surface being provided with the drive wiring and a solder resist, faces a surface of an element substrate, that surface being provided with display wiring. Furthermore, the drive wiring and the display wiring are electrically coupled to each other, and the solder resist is in contact with the element substrate.

This Nonprovisional application claims priority under 35 U.S.C. § 119(a) on patent application No. 2004-123133 filed in Japan on Apr. 19, 2004, the entire contents of which are hereby incorporated by reference.

### FIELD OF THE INVENTION

The present invention relates to a coupling structure of electronic components. More specifically, the present invention relates to a coupling structure that allows a liquid crystal driver and a liquid crystal panel to be electrically coupled to each other.

### BACKGROUND OF THE INVENTION

A liquid crystal display device has conventionally been used as a COF (Chip On Film) module device. Such a liquid crystal display device includes: a liquid crystal driver including a flexible substrate on which a driver chip for driving elements of a liquid crystal panel is provided; and the liquid crystal panel including an element substrate and an opposing substrate. The liquid crystal driver and the liquid crystal panel are electrically coupled to each other.

FIG. 7 is a cross section showing a coupling structure of a liquid crystal driver 101 and a liquid crystal panel 102. The liquid crystal driver 101 includes a flexible substrate 103 and a driver chip 104. The flexible substrate 103 is made of a polyimide film. On the flexible substrate 103, drive wiring 105 made of Cu is formed by etching. On the drive wiring 105, a solder resist 106 is formed. This solder resist 106 is formed so as to allow an end part 107 of the drive wiring 105 to be exposed. The driver chip 104 is connected to the surface of the flexible substrate 103. Furthermore, a gap between the flexible substrate 103 and the driver chip 104 is filled with interfacial resin 108.

The liquid crystal panel 102 includes an element substrate 109 and an opposing substrate 110. When the liquid crystal display device adopts TFT (Thin Film Transistor) structure, pixels each including a TFT element are provided in a matrix manner, on the element substrate 109 of the liquid crystal panel 102. On the entire surface of the element substrate 109, source lines and gate lines, which are display wiring 111, are provided.

It is noted that the opposing substrate 110 is smaller than the element substrate 109. On this account, a part of the display wiring 111, the part being formed on the end part of the element substrate 109, is not covered with the opposing substrate 110, so as to be exposed. This exposed part of the display wiring 111 acts as connecting terminals for the connection with the liquid crystal driver 101.

The liquid crystal driver 101 and the liquid crystal panel 102 are connected to each other using an anisotropic conductive adhesive (hereinafter, ACF) 112. The ACF 112 is made up of resin 113 and conductive beads 114, and the flexible substrate 103 and the element substrate 109 are bonded together by the resin 113. The conductive beads 114 are in contact with (i) a part of the drive wiring 105 on the flexible substrate 103, the part being exposed, and (ii) the connecting terminals on the element substrate 109. With this, the liquid crystal driver 101 and the liquid crystal panel 102 are electrically coupled to each other. This coupling is done by thermo-compression bonding.

A frame area of a liquid crystal monitor is preferably formed as small as possible. For this reason, commercially-available liquid crystal monitors and the like are arranged such that the liquid crystal driver 101 connected to the liquid crystal panel 102 is folded. FIG. 8 shows how the liquid crystal driver 101 is folded. As in the figure, the flexible substrate 103 of the liquid crystal driver 101 is folded so as to wrap up the end part of the element substrate 109 of the liquid crystal panel 102.

Patent Document 1 describes such a structure that a liquid crystal glass of a liquid crystal panel is connected with TAB components by means of ACF. FIG. 9 shows a coupling structure taught by Patent Document 1.

As shown in FIG. 9, TAB components 117 are connected to the surface of a liquid crystal glass substrate 116 of a liquid crystal panel 115. This connection is made by compression bonding using an ACF tape 118 made of resin 119 and conductive beads 120. This ACF tape 118 is so broad as to reach a solder resist section 121, and by compression bending, the ACF tape 118 is adhered also to the solder resist section 121. In this manner, since the ACF tape 118 adopted in this arrangement is so broad as to override the solder resist section 121, the ACF tape 118 entirely covers drive wiring 123 formed on the end part of the flexible substrate 122 that is one of the TAB parts 117.

The ACF tape 118 is basically used for connecting the liquid crystal panel 115 and the TAB components 117. However, in Patent Document 1, the ACF tape covers the wiring around the solder resist, which has conventionally been exposed and not covered with the ACF tape. This improves the reliability of the wiring.

Also in Patent Document 1, the flexible substrate 122 is folded in order to downsize the frame area of the liquid crystal monitor. In case of adopting TCP (Tape Carrier Package) in which a driver chip is mounted on a polyimide film as in the case of COF, it is necessary to estimate folding positions before determining positions of folding slits. For this reason, the folding positions are not arbitrarily determined in the case of adopting TCP. On the other hand, according to COF, it is possible to arbitrarily determine the folding positions except an area around the driver chip. Therefore, according to COF, it is possible to obtain a higher degree of freedom in terms of folding positions, as compared to TCP.

(Patent Document 1) Japanese Laid-Open Patent Application No. 2003-66479 (published on Mar. 5, 2003)

However, in the arrangement shown in FIG. 7, the end part 107 of the drive wiring 105 is exposed between the solder resist 106 and the ACF 112 of the liquid crystal driver 101. If moisture or dust is adhered to this exposed part, short-circuit or leakage failure may occur.

In recent years, the driving scheme of liquid crystal displays has shifted from line-reversal driving scheme to dot-reversal driving scheme. Also, liquid crystal displays have significantly been upsized. For these reasons, high voltages with opposite polarities are always applied to source lines adjacent to a liquid crystal display. On account of this structure, ion migration is induced by adhered moisture, thereby causing short-circuit and leakage failure.

As described above, the connection between the liquid crystal driver 101 and the liquid crystal panel 102 is realized by bonding the flexible substrate 103 with the ACF 112 and by bonding the element substrate 109 with the ACF 112. However, since the connection between the flexible substrate 103 and the ACF 112 is typically weak, the flexible substrate 103 may be detached from the ACF 112.

If such separation occurs, moisture may enter the inside of the liquid crystal driver 101. The moisture entering the liquid crystal driver 101 is adhered not only to the exposed part of the drive wiring 105 but also that part of the drive wiring 105 which should have been connected to the element substrate 109 by the ACF 112. In this case, the reliability of the wiring significantly decreases.

As FIG. 8 illustrates, the folded part of the flexible substrate 103 is topically under stress. For this reason, the drive wiring 105 may break down at the folded part. Moreover, the folded part may be in touch with the end part of the element substrate 109. In such a case, since the drive wiring 105 at the folded part is exposed, the drive wiring 105 directly contact the end part of the element substrate 109. This damages and breaks down the drive wiring 105.

On the other hand, in the arrangement shown in FIG. 9 of Patent Document 1, the end part 123 of the drive wiring 122 is not exposed. With this, the above-described problem, i.e. the adhesion of moisture or dust to the exposed wiring, is prevented. However, since the connection between the flexible substrate 122 and the element substrate 116 is made by means of the ACF tape 118, the separation of the ACF tape 118 from the flexible substrate 122 is not prevented, so that the problem of moisture entering the liquid crystal driver 117 is still unsolved.

In the arrangement shown in FIG. 9, it seems as if the ACF tape 118 protects the drive wiring 122 at the folded part, after folding the flexible substrate 122. However, the drive wiring 121 at the folded part is in fact not protected, because of the following reason.

As described above, the liquid crystal driver 117 and the liquid crystal panel 115 after thermo-compression bonding are electrically coupled to each other via the conductive beads 120. On this account, the gap between the liquid crystal driver 117 and the liquid crystal panel 115 is identical with or shorter than the diameter of each conductive bead 120. Furthermore, in consideration of further compression at the time of the thermo-compression bonding, the aforesaid gap is shorter than the diameter of the conductive bead 120 in most cases.

The diameter of the conductive bead 120 is typically 4 μmφ, suggesting that the liquid crystal driver 117 and the liquid crystal panel 115 are connected to each other by the ACF tape 118 that is 4 μm thick or less. The 4 μm-thick ACF tape 118 is not strong enough to prevent the breakdown of the drive wiring 121 at the time of folding the flexible substrate 122 and to prevent the breakdown of the drive wiring 121 on account of the contact with the end part of the element substrate 116. Therefore, Patent Document 1 fails to protect the drive wiring 121 at the folded parts of the flexible substrate 122, and hardly prevents the breakdown of the drive wiring which may occur at the time of folding.

To prevent the drive wiring from touching the end part of the element substrate on the occasion of folding the flexible substrate, it is possible to interpose silicone resin between the side of the element substrate and the flexible substrate. However, this idea unfits for mass-production, because silicone resin material and a step of applying the silicone resin are additionally required.

### SUMMARY OF THE INVENTION

The present invention was done to solve the above-described problem. The objective of the present invention is therefore to realize a coupling structure of electronic components, which prevents drive wiring from breaking down even when a flexible substrate is folded, and improves the reliability of the wiring.

To solve the above-described problem, a coupling structure of electronic components of the present invention, for connecting (i) a first electronic component in which first wiring and a protective film for protecting the first wiring are provided on a surface of a first substrate, with (ii) a second electronic component in which second wiring is provided on a surface of a second substrate, is characterized in that, that surface of the first substrate on which the first wiring and the protective film are provided faces that surface of the second substrate on which the second wiring is provided, so that the first wiring and the second wiring are electrically coupled to each other, and the protective film is directly in contact with the second substrate.

According to this arrangement, on the first substrate of the first electronic component, the first wiring and the protective film are provided. In the meanwhile, on the second substrate of the second electronic component, the second wiring is provided. That surface of the first substrate which is provided with the first wiring and the protective film faces that surface of the second substrate which is provided with the second wiring.

On this account, the first wiring and the second wiring, which are provided on the respective surfaces opposing to each other, can be electrically coupled to each other. This makes it possible to electrically couple the first electronic component with the second electronic component. Also, the protective film on the first substrate is directly in touch with the second substrate. This ensures the connection between the first and second substrates. It is therefore possible to prevent the first substrate from separating from the second substrate.

Furthermore, since the protective film is directly in contact with the second substrate, the first wiring that contributes to the connection to the second wiring is not exposed. On this account, the first wiring does not directly contact the second substrate, even when the first substrate is folded. This prevents the first wiring from breaking down. In this manner, the reliability of the wiring regarding the coupling structure of the electronic components is improved.

To solve the above-described problem, a coupling structure of electronic components of the present invention, for connecting (i) a first electronic component in which first wiring and a protective film for protecting the first wiring are provided on a surface of a first substrate, with (ii) a second electronic component in which second wiring is provided on a surface of a second substrate, is characterized in that, that surface of the first substrate on which the first wiring and the protective film are provided faces that surface of the second substrate on which the second wiring is provided, so that the first wiring and the second wiring are electrically coupled to each other, and the protective film is in contact with the second substrate, via an adhesive.

According to this arrangement, on the first substrate of the first electronic component, the first wiring and the protective film are provided. In the meanwhile, on the second substrate of the second electronic component, the second wiring is provided. That surface of the first substrate which is provided with the first wiring and the protective film faces that surface of the second substrate which is provided with the second wiring.

On this account, the first wiring and the second wiring, which are provided on the respective surfaces opposing to each other, can be electrically coupled. This makes it possible to electrically couple the first electronic component with the second electronic component. Also, the protective film on the first substrate is directly in touch with the second substrate. This ensures the connection between the first and second substrates. It is therefore possible to prevent the first substrate from separating from the second substrate.

Furthermore, since the protective film is in contact with the second substrate via the adhesive, the first wiring that contributes to the connection to the second wiring is not exposed. On this account, the first wiring does not directly contact the second substrate, even when the first substrate is folded. This prevents the first wiring from breaking down. In this manner, the reliability of the wiring regarding the coupling structure of the electronic components is improved.

For a fuller understanding of the nature and advantages of the invention, reference should be made to the ensuing detailed description taken in conjunction with the accompanying drawings.

### BRIEF DESCRIPTION OF THE DRAWINGS

FIG. 1 relates to an embodiment of the present invention, and is a cross section that schematically shows a coupling structure of a liquid crystal driver and a liquid crystal panel.

FIG. 2 is an oblique perspective view schematically showing the liquid crystal driver of FIG. 1.

FIG. 3 is a cross section that schematically shows steps of connecting the liquid crystal driver and the liquid crystal panel of FIG. 1.

FIG. 4 is a cross section that schematically shows how the liquid crystal driver of FIG. 1 is folded.

FIG. 5 is an oblique perspective view schematically showing another liquid crystal driver of FIG. 1.

FIG. 6 is an oblique perspective view schematically showing another liquid crystal driver of FIG. 1.

FIG. 7 is a cross section showing a coupling structure of a liquid crystal driver and a liquid crystal panel of a conventional arrangement.

FIG. 8 is a cross section showing how the liquid crystal driver of FIG. 7 is folded.

FIG. 9 is a cross section showing another coupling structure of the liquid crystal driver and the liquid crystal panel of the conventional arrangement.

### DESCRIPTION OF THE EMBODIMENTS

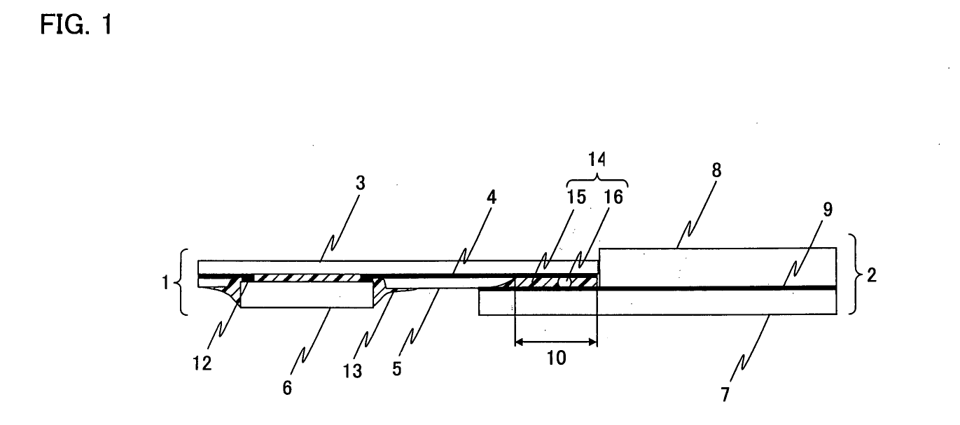

The following will discuss an embodiment of the present invention in reference to FIGS. 1 through 6. The present embodiment illustrates a coupling structure of a liquid crystal driver and a liquid crystal panel of a liquid crystal display device, but the present invention is not limited to this embodiment.

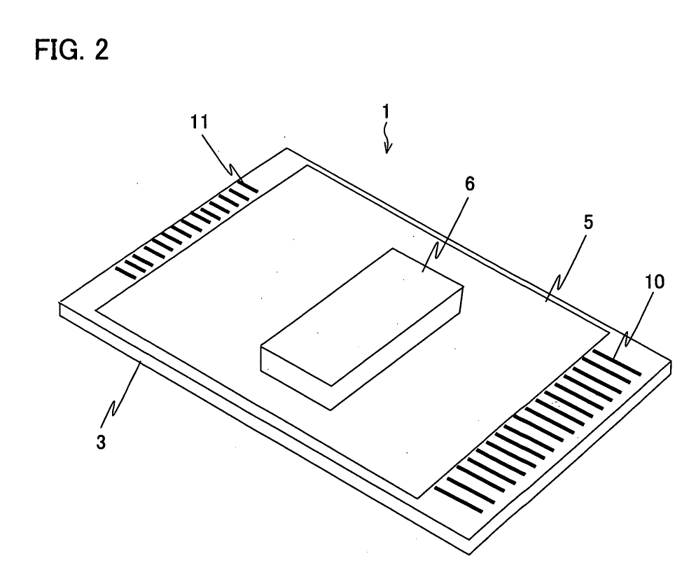

FIG. 1 is a cross section schematically showing a coupling structure of a liquid crystal driver (first electronic component) and a liquid crystal panel (second electronic component) of the present embodiment. FIG. 2 is an oblique perspective view showing schematic arrangement of the liquid crystal driver 1. As FIGS. 1 and 2 show, the liquid crystal driver 1 includes a flexible substrate (first substrate) 3, drive wiring (first wiring) 4, a solder resist (protective film) 5, and a driver chip 6. The liquid crystal panel 2 includes an element substrate (second substrate) 7, an opposing substrate (third substrate) 8, and display wiring (second wiring) 9.

The flexible substrate 3 acts as a base of the liquid crystal driver 1, and is made of, for instance, polyimide film so as to be flexible. The thickness of the flexible substrate 3 is, for instance, 38 μm, but can be appropriately determined in line with the purposes.

On this flexible substrate 3, the drive wiring 4 is formed. This drive wiring 4 is made of Cu and formed by, for instance, etching. On the drive wiring 4 thus arranged, Sn is provided by electroless plating.

On the flexible substrate 3 on which the drive wiring 4 has been formed, the solder resist 5 is formed in order to protect the drive wiring 4. The solder resist 5 has a rectangular shape, in order to simplify the printing of the same. To allow an end part of the drive wiring 4 to act as electrodes, the solder resist 5 is formed in such a manner as to allow the end part of the drive wiring 4 to be exposed.

The exposed end part of the drive wiring 4 acts as electrodes for the connection with another substrate, and is used as input/output terminals. More specifically, the end part of the drive wiring 4 acts as output outer leads (hereinafter, output OL) 10 for the connection with the liquid crystal panel 2 and input outer leads 11 for the connection with another circuit substrate.

Through the solder resist 5, an opening (not illustrated) termed device hole is made for the connection with the below-described driver chip 6. That part of the drive wiring 4 which is exposed through the opening acts as inner leads (not illustrated) for the connection with the driver chip 6.

The driver chip 6 is provided for driving elements on the liquid crystal panel 2. On a surface of the driver chip 6, the surface contacting the flexible substrate 3, protruding electrodes 12 made of Au and 10 μm in height are formed by plating. To this driver chip 6, all of the protruding electrodes 12 and the flexible substrate 3 are connected altogether by means of face-down ILB (Inner Lead Bonding). This connection is done by thermo-compression bonding, so that Au of which the protruding electrodes 12 are made is eutectic-bonded with Sn that is provided on the flexible substrate 3 by electroless plating. Conditions of the thermo-compression bonding for the connection between the driver chip 6 and the flexible substrate 3 are, for instance, an interfacial temperature of 380 though 460° C., a pressure of 150 through 250N, and a time of 0.5 through 2 seconds.

After connecting the driver chip 6 with the flexible substrate 3 by the face down ILB, interfacial resin 13 is filled into a gap between the driver chip 6 and the flexible substrate 3. Then the flexible substrate 3 is deformed so as to have a predetermined outer shape, and consequently the liquid crystal driver 1 is obtained.

In the liquid crystal panel 2, the opposing substrate 8 is provided in such a manner as to face the element substrate 7. Also, between the element substrate 7 and the opposing substrate 8, a liquid crystal layer (not illustrated) is interposed. On the element substrate 7, pixels (not illustrated) each having a TFT element are provided in a matrix manner. The opposing substrate 8 is provided with color filters (not illustrated) corresponding to the respective pixels of the element substrate 7. The opposing substrate 8 also acts as an electrode through which a voltage is applied to liquid crystal.

The surface area of the opposing substrate 8 is smaller than that of the element substrate 7. In other words, the opposing substrate 8 is smaller than the element substrate 7, in terms of outer shape. On this account, a peripheral part of the element substrate 7 protrudes from the opposing substrate 8. That is to say, the liquid crystal panel 2 has a so-called frame part at a periphery thereof. This frame part is the peripheral part of the element substrate 7.

To the TFT elements of the respective pixels on the element substrate 7, source lines and gate lines, which are the display wiring 9, are connected so as to form a lattice. This display wiring 9 covers the end part (frame part) of the element substrate 7. That part of the display wiring 9 which is provided on the frame part acts as connecting terminals for the connection to the liquid crystal driver 1 (hereinafter, these connecting terminals will be referred to as input terminals of the liquid crystal panel 2).

Referring to FIG. 1, the coupling structure of the liquid crystal driver 1 and the liquid crystal panel 2 will be specifically described.

The liquid crystal driver 1 and the liquid crystal panel 2 are arranged such that, a surface of the flexible substrate 3 faces a surface of the element substrate 7, whereby the drive wiring 4 and the solder resist 5 are formed on that surface of the flexible substrate 3, while the display wiring 9 is formed on that surface of the element substrate 7. The flexible substrate 3 and the element substrate 7 are bonded with each other using an anisotropic conductive adhesive (hereinafter, ACF) 14. With this, the output OL 10 are connected to the respective input terminals of the liquid crystal panel 2, via the ACF 14.

The ACF 14 is made of resin 15 and conductive beads 16, more specifically, the conductive beads 16 are dispersed in the resin 15. The resin 15 of the ACF 14 acts as an adhesive for ensuring the bonding of the liquid crystal driver 1 and the liquid crystal panel 2 and hence improving the mechanical strength. The conductive beads 16 are provided for allowing the liquid crystal driver 1 and the liquid crystal panel 2 to be electrically coupled to each other.

That is to say, the liquid crystal driver 1 and the liquid crystal panel 2 are electrically coupled to each other for the reason that the input terminals of the liquid crystal panel 2 and the output OL 10 contact the conductive beads 16. In this manner, the liquid crystal driver 1 and the liquid crystal panel 2 are electrically coupled to each other via the conductive beads 16 in the ACF 14, and are tightly bonded to each other by the resin 15.

Furthermore, as shown in FIG. 1, the solder resist 5 formed on the flexible substrate 3 is in contact with the frame part of the element substrate 7. On this account, the output OL 10 are not exposed at the connecting part between the liquid crystal driver 1 and the liquid crystal panel 2, and the output OL 10 are detached for a certain distance from the end part of the element substrate 7 towards the opposing substrate 8.

A part of the solder resist 5 formed on the flexible substrate 3 is in contact with the frame part of the element substrate 7. This part of the solder resist 5 is, for instance, a peripheral part of the solder resist 5 or an end part of the solder resist 5, the end part being on the output OL 10 side.

The solder resist 5 may be directly in contact with the frame part of the element substrate 7, or may be in contact with the frame part via the ACF 14. The part of the solder resist 5, which is in contact with the frame part of the element substrate 7, may be arranged such that a portion of the part is directly in contact with the frame part, while the remaining portion of the part is in contact with the frame part via the ACF 14. Hereinafter, descriptions such as “the solder resist 5 ‘contacts’ the element substrate 7” include all of the aforesaid ways of contact.

The flexible substrate 3 is provided so that the solder resist 5 is in contact with the frame part of the element substrate 7. More preferably, the flexible substrate 3 is provided so that the end part of the flexible substrate 3 is in contact with the end part of the opposing substrate 8. This makes it possible to enlarge an area of the solder resist 5 in contact with the frame part of the element substrate 7.

The solder resist 5 is preferably 10 μm thick or less. Since the solder resist 5 is in contact with the frame part of the element substrate 7, when the thickness of the solder resist 5 is more than 10 μm, the gap between the liquid crystal driver 1 and the liquid crystal panel 2 is too wide. The solder resist 5 may be arranged such that, a part of the solder resist 5, the part being in contact with the frame part of the element substrate 7, is thinner than the remaining part of the solder resist 5 not being in contact with the frame part. In other words, a part of the solder resist 5, the part being sandwiched between the flexible substrate 3 and the element substrate 7, may be thinner than the remaining part of the solder resist 5 that is not sandwiched. In such a case, at the connecting part, the thickness of the solder resist 5 is in conformity with the gap between the liquid crystal driver 1 and the liquid crystal panel 2,while the solder resist 5 at the parts other than the connecting part has a thickness required for protecting the drive wiring 4.

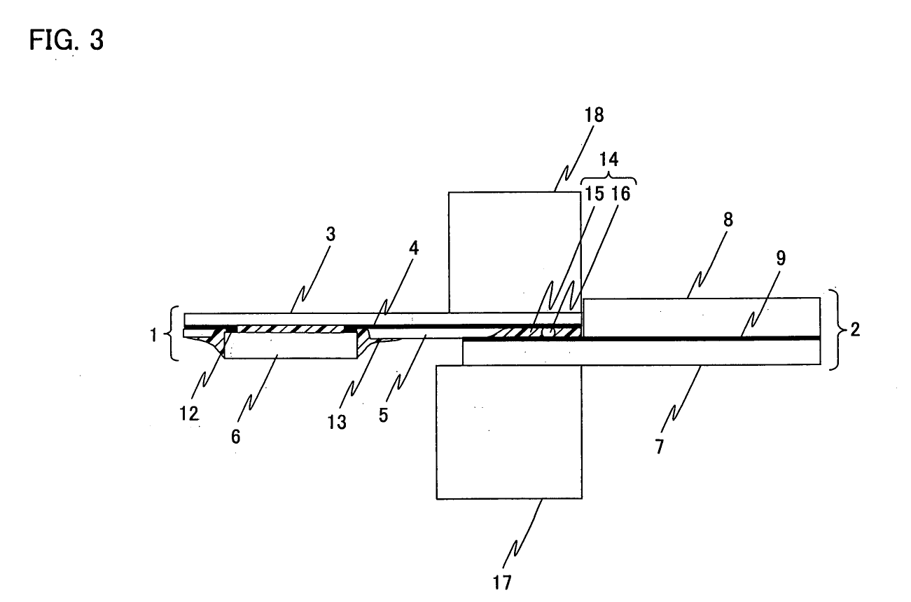

Now, how the liquid crystal driver 1 and the liquid crystal panel 2 are connected to each other is illustrated. The connection can be done by thermo-compression bonding. FIG. 3 shows a step of thermo-compression-bonding performed in the present embodiment. As shown in this figure, on a part where the liquid crystal driver 1 and the liquid crystal panel 2 are connected to each other, thermo-compression bonding member is provided. This thermo-compression bonding member is made up of a compression-bonding supporter 17 and a compression bonding section 18.

First, the liquid crystal panel 2 is placed on the compression boding supporter 17. More specifically, the frame part of the liquid crystal panel 2 is placed on the compression bonding supporter 17. After applying the ACF 14 to the frame part, the liquid crystal driver 1 is placed on the ACF 14, in such a manner that the output OL 10 are placed on the ACF 14 while the solder resist 5 is placed on the element substrate 7.

Then the compression bonding section 18 is placed on the flexible substrate 3 at the connecting part. With this, at the connecting part, the liquid crystal driver 1 and the liquid crystal panel 2 are sandwiched between the compression bonding supporter 17 and the compression bonding section 18. Thereafter, the connecting part is heated by a heating member (not illustrated), and compression-bonded by the compression bonding supporter 17 and the compression bonding section 18.

With this, the resin 15 in the ACF 14 melts and then hardens up. At the same time, the conductive beads 16 deform on account of the compression-bonding. As a result of the melt and hardening of the resin 15, the liquid crystal driver 1 and the liquid crystal panel 2 are firmly bonded with each other. Also, the output OL and the input terminals of the liquid crystal panel are in contact with the conductive beads 16, so that the liquid crystal driver 1 and the liquid crystal panel 2 are electrically coupled to each other. It is noted that the deformation of the conductive beads 16 results in the enlargement of an area at which the liquid crystal driver 1 and the liquid crystal panel 2 are electrically coupled to each other.

In order to cause the liquid crystal driver 1 and the liquid crystal panel 2 to be electrically coupled to each other, the aforesaid thermo-compression bonding is performed in such a manner as to keep the gap at the connecting part to be not wider than the diameter of each conductive bead 16. In such a case, to prevent neighboring terminals of the output OL 10 or of the input terminals of the liquid crystal panel 2 from short-circuiting with each other, the ACF 14 is arranged such that a dispersion amount of the conductive beads 16 in the resin 15 is adjusted. In this manner, a dispersion amount of the conductive beads 16 in the ACF 14 is preferably in line with the interval between the terminals. The ACF 14 may be shaped like a long tape. In such a case, the connection between the liquid crystal driver 1 and the liquid crystal panel 2 can be performed altogether.

As described above, the ACF 14 melts on account of the thermo-compression bonding. In response to an application of pressure, this melted ACF 14 extends toward the solder resist 5, thereby filling the gap between the solder resist 5 and the element substrate 7. As the ACF 14 hardens up, the solder resist 5 is bonded with the element substrate 7 via the ACF 14. This ensures the bonding between the liquid crystal driver 1 and the liquid crystal panel 2.

Conditions of the aforesaid thermo-compression bonding can be set in many ways, as long as the liquid crystal driver 1 and the liquid crystal panel 2 are connected to each other. For instance, a heating temperature is in the range of 190 through 200° C., an applied pressure is in the range of 2.8 through 3.2 MP, and a time for compression-bonding is in the range of 20 through 30 seconds.

At the time of performing the thermo-compression bonding, the compression bonding section 18 is provided on the flexible substrate 3 at the connecting part. In this case, the compression bonding section 18 is provided on a part of the flexible substrate 3, the output OL 10 being formed on that part. More preferably, the compression bonding section 18 is provided on a part of the flexible substrate 3, not only the output OL 10 but also the solder resist 5 being formed on that part.

That is to say, it is preferable that a surface of the compression bonding section 18, the surface at which the compression bonding section 18 is connected to the flexible substrate 3, covers not only the output OL 10 but also a part where the solder resist 5 is in contact with the element substrate 7. With this, the surface of the solder resist 5 contacting the element substrate 7 is, by the thermo-compression bonding, melted and then hardened up. As a result, the solder resist 5 is bonded with the element substrate 7. This further ensures the bonding between the liquid crystal driver 1 and the liquid crystal panel 2.

As a result of the above, the coupling structure shown in FIG. 1, by which the liquid crystal driver 1 and the liquid crystal panel 2 are connected to each other, is realized.

In this manner, the solder resist 5 on the flexible substrate 3 is bonded with the frame part of the element substrate 7, so that the connection between the liquid crystal driver 1 and the liquid crystal panel 2 is realized by the connection-via the ACF 14 and the connection via the solder resist 5. This ensures the bonding of the flexible substrate 3 as compared to a case of connection sorely by the ACF 14, so that the separation of the flexible substrate 3 is prevented.

For instance, in a case where each of the output OL 10 is 2 mm long and a distance (width of the frame part) between the end part of the opposing substrate 8 and the end part of the element substrate 7 is 5 mm, a part of the solder resist 5, the part being in contact with the element substrate 7, is 3 mm long, provided that the end part of the flexible substrate 3 is placed so as to be in touch with the end part of the opposing substrate 8. In short, a distance between the end part of the solder resist 5 and the end part of the opposing substrate 8 is 2 mm.

In this case, the liquid crystal driver 1 and the liquid crystal panel 2 are connected to each other via (i) the ACF 14 which is 2 mm wide, and (ii) the solder resist 5 which is 3 mm wide. On this account, the output OL 10 are detached for 3 mm through 5 mm from the end part of the element substrate 7. That is, the output OL 10 are detached from the end part of the element substrate 7, from which moisture enters. As a result, moisture must take a longer path to reach the output OL, as compared to the conventional cases.

As described above, the separation of the flexible substrate 3 is prevented, so that the intrusion of moisture into the liquid crystal driver 1 is successfully prevented. Even if moisture enters the liquid crystal driver 1, the distance between the end part of the element substrate 7 and the output OL 10 is long, and hence it is possible to prevent the moisture from reaching the output OL 10. Note that, the wider the frame part of the element substrate 7 is, the larger an area where the solder resist 5 and the element substrate 7 contacts becomes. Therefore, the prevention of the intrusion of moisture is further ensured.

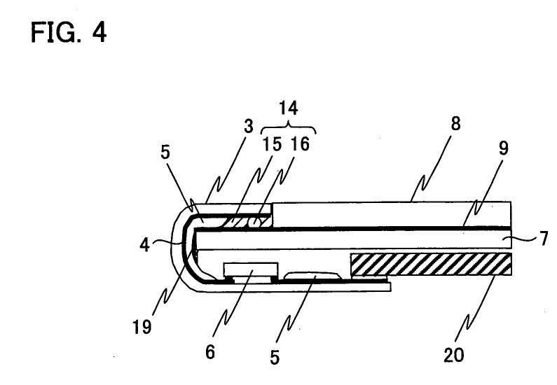

The liquid crystal driver 1 being connected to the liquid crystal panel 2 is folded with a view to being incorporated into the liquid crystal monitor that is a final product. This folding is performed in such a manner that the flexible substrate 3 of the liquid crystal driver 1 is folded so as to wrap up the end part of the element substrate 7 of the liquid crystal panel 2. FIG. 4 shows how the liquid crystal driver 1 connected to the liquid crystal panel 2 is folded.

As shown in this figure, even after the flexible substrate 3 is folded, the solder resist 5 is formed at the folded part. On this account, the wiring on the flexible substrate 3 does not break down even if the folding is performed.

Furthermore, since the solder resist 5 wraps up the end part of the element substrate 7, the driver wiring 4 formed on the liquid crystal driver 1, such as the output OL 10, does not directly contact the end part of the element substrate 7. On this account, the drive wiring 4 does not break down on account of the contact with the end part of the element substrate 7. In other words, the solder resist 5 protects the drive wiring 4 on the liquid crystal driver 1.

To the input outer leads 11 of the folded flexible substrate 3, another circuit substrate 20 is connected.

It is noted that, after folding the liquid crystal driver 1 connected to the liquid crystal panel 2, silicone resin 19 may be applied to the folded part. In this case, the silicone resin 19 fills a gap formed when the flexible substrate 3 is folded. In this manner, the drive wiring 4 is completely covered, on the occasion of the thermo-compression bonding, by the melted ACF 14 filling every gap, and furthermore a gap formed at the time of the folding is filled with the silicone resin 19. As a result, it is possible to effectively prevent moisture and impurities from entering the liquid crystal driver 1, so that the reliability of the wiring is improved.

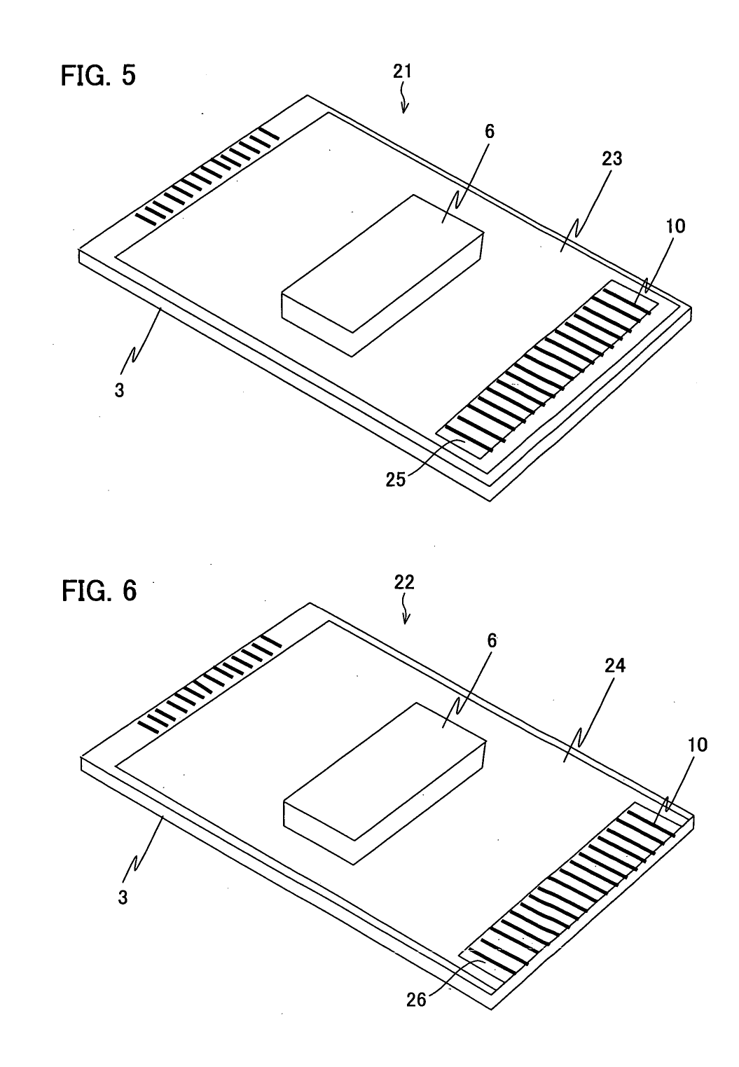

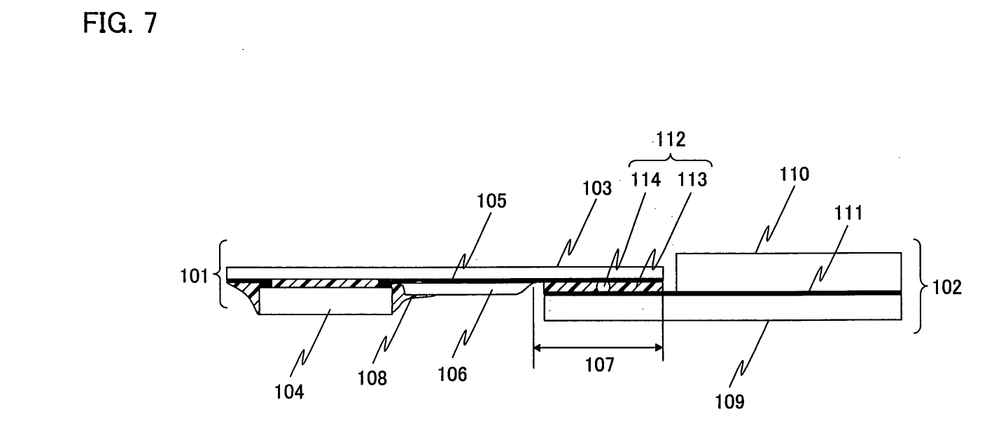

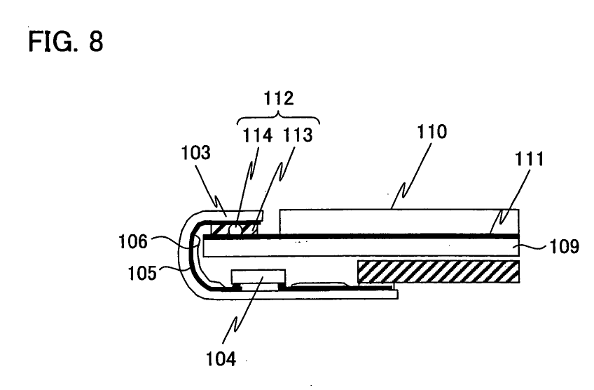

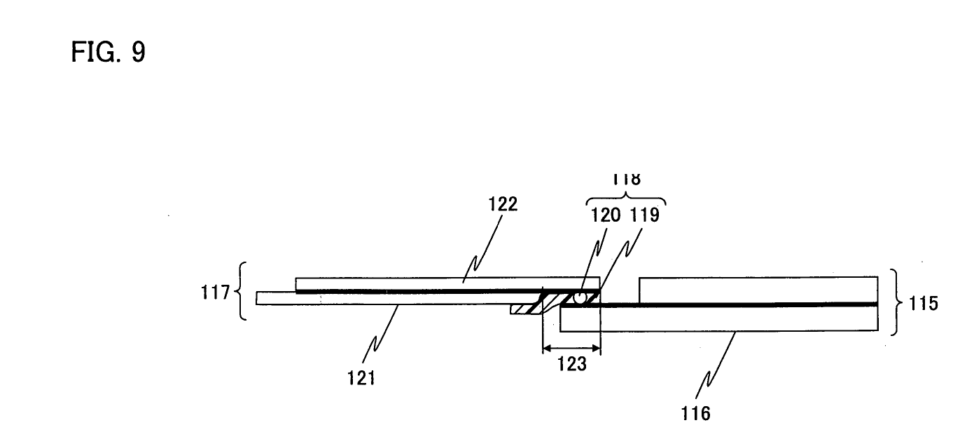

In the above, the liquid crystal driver 1 is arranged such that the solder resist 5 is formed in such a manner as to allow the end part of the drive wiring 4 to be exposed. However, the liquid crystal driver of the present invention is not limited to this, so that, for instance, liquid crystal drivers 21 and 22 shown in FIGS. 5 and 6 may be adopted.

The liquid crystal driver 21 shown in FIG. 5 is arranged in such a manner that the solder resist 23 covers an end part of the drive wiring 4 formed on the flexible substrate 3, the end part being on the output OL 10 side. Through this solder resist 23, a rectangular-shaped opening 25 is formed at a part acting as the output OL 10. The output OL 10 are exposed through this opening 25. The opening 25 of the solder resist 23 is formed so as to allow the output OL 10 to be exposed. When the opening 25 has a rectangular shape, a step of forming this opening can be simplified.

In the liquid crystal driver 21 shown in FIG. 5, the output OL 10 are exposed through the rectangular-shaped opening 25. On this account, at the end part of the flexible substrate 3, not the output OL 10 but the solder resist 23 is formed. Therefore, the output OL 10 are surrounded by the solder resist 23. When the connection of the present invention is performed using the liquid crystal driver 21 being thus arranged, the output OL 10 at the connecting part can be completely isolated from the outside. This ensures the prevention of the break down of the drive wiring 4, and further improves the reliability of the wiring.

In the liquid crystal driver 22 shown in FIG. 6, the solder resist 24 is formed so as to cover an end part of the drive wiring 4 formed on the flexible substrate 3, the end part being on the output OL 10 side. Furthermore, through the solder resist 24, an opening 26 is made at a part acting as the output OL 10, so that the output OL 10 are exposed through the opening 26. This opening 26 reaches the end part of the flexible substrate 3. In other words, the opening 26 of the solder resist 24 extends to that end part of the flexible substrate 3 which is on the output OL 10 side. In this case, the output OL 10 can be extended to the end part of the flexible substrate 3.

The frame part of the element substrate 7 cannot be generally used for purposes other than the connection between the liquid crystal driver and the liquid crystal panel, so that the width of the frame part is restrained to the minimum, in consideration of the downsizing of the liquid crystal monitor. In the liquid crystal driver 22 shown in FIG. 6, since the output OL 10 are extended to the end part of the flexible substrate 3, the connection with the liquid crystal panel 2 is successfully realized even if the frame part of the element substrate 7 is narrow. This ensures the prevention of the break down of the drive wiring 4, improves the reliability of the wiring, and also allows the liquid crystal monitor to be downsized.

Also in cases where the liquid crystal driver 21 or 22 is adopted, the connection between the liquid crystal driver 21 or 22 and the liquid crystal panel 2 can be made by the aforesaid thermo-compression bonding.

The present invention can be rephrased as a structure of mounting a COF module device having a coupling structure by which a flexible substrate having a wiring pattern and a surface protective film protecting the wiring pattern is connected to and electrically coupled with a hard substrate having another wiring pattern, by causing the surfaces having the respective terminals to face each other, wherein the surface protective film of the flexible substrate is in touch with the hard substrate.

In this case, it is preferable that the hard substrate is a part of a liquid crystal display or a flat display panel such as a plasma display, and on the flexible substrate a flat display panel driver is mounted.

It is also preferable that the flexible substrate and the hard substrate are connected to each other by an anisotropic conductive adhesive, and the protective film of the flexible substrate is bonded with the hard substrate.

The surface protective film of the flexible substrate is preferably 10 μm thick or less, and the surface protective film of the flexible substrate is preferably in contact with the entirety of the hard substrate, i.e. from one edge to the other edge.

A distance to the edge of the surface protective film in contact with the hard substrate is preferably 2 mm or less. Also a part of the surface protective film, the part around a part of the flexible substrate where the protective film is not provided in consideration of electrical coupling with the hard substrate, is preferably thinner than the remaining part of the surface protective film.

The flexible substrate is preferably arranged such that an opening is made through a part of the protective film of the flexible substrate contacting the hard substrate, and a terminal for the connection with the hard substrate is exposed through the opening. Moreover, the opening is preferably made on the side of the edge of the flexible substrate.

As described above, a coupling structure of electronic components of the present invention, for connecting (i) a first electronic component in which first wiring and a protective film for protecting the first wiring are provided on a surface of a first substrate, with (ii) a second electronic component in which second wiring is provided on a surface of a second substrate, is arranged such that, that surface of the first substrate on which the first wiring and the protective film are provided faces that surface of the second substrate on which the second wiring is provided, so that the first wiring and the second wiring are electrically coupled to each other, and the protective film is directly in contact with the second substrate.

As described above, a coupling structure of electronic components of the present invention, for connecting (i) a first electronic component in which first wiring and a protective film for protecting the first wiring are provided on a surface of a first substrate, with (ii) a second electronic component in which second wiring is provided on a surface of a second substrate, may be arranged such that, that surface of the first substrate on which the first wiring and the protective film are provided faces that surface of the second substrate on which the second wiring is provided, so that the first wiring and the second wiring are electrically coupled to each other, and the protective film is in contact with the second substrate, via an adhesive.

In the coupling structure of the present invention, it is preferable that a part of the protective film is directly in contact with the second substrate. According to this arrangement, a part of the protective film is directly in contact with the second substrate, while another part of the protective film is in contact with the second substrate via an adhesive. With this, even if a gap is partially formed between the protective film and the second substrate, it is possible to connect the first substrate with the second substrate, by filling an adhesive.

In the coupling structure of the present invention, the adhesive preferably includes an anisotropic conductive adhesive. This allows the first and second electronic components to be bonded with each other. With this, the connection between the first and second electronic components is ensured.

In the coupling structure of the present invention, the first wiring and the second wiring are preferably connected to each other by an anisotropic conductive adhesive. The anisotropic conductive adhesive includes a conductive agent, in addition to an adhesive. For this reason, the first wiring and the second wiring are electrically coupled to each other via the conductive agent. This allows the first and second electronic components to be electrically coupled to each other.

In the coupling structure of the present invention, the protective film is preferably bonded with the second substrate. This further ensures the bonding between the first and second electronic components.

In the coupling structure of the present invention, the protective film is preferably 10 μm thick or less. Also, a part of the protective film, the part being sandwiched between the first substrate and the second substrate, is preferably thinner than a remaining part of the protective film. If the protective film at the connecting part between the first and second electronic components is thick, a gap between the first and second electronic components is too wide, so that the electrical coupling is hindered. Since the above-described arrangement can narrow the gap between the first and second electronic components, the electrical coupling is ensured.

In the coupling structure of the present invention, the first substrate is preferably flexible. This allows the first substrate to be foldable. As a result, the size of the first and second electronic component connected to each other can be reduced. Furthermore, since the first wiring does not break down even if the first substrate is folded, the wiring in the coupling structure is highly reliable.

The coupling structure of the present invention is preferably arranged such that the second electronic component includes a third substrate that faces the second substrate and that is smaller in terms of surface area than the second substrate, and the first substrate is in contact with the third substrate.

According to this arrangement, since the surface area of the third substrate is smaller than that of the second substrate, a peripheral part of the second substrate is exposed when the second and third substrates are provided so as to face each other. Therefore, an area of the first substrate in contact with the second substrate can be enlarged by providing the first substrate to be in contact with the third substrate. As a result, an area of the protective film, which is on the first substrate and in contact with the second substrate, can be enlarged. Therefore, the prevention of the break down of the first wiring is further ensured, and the connection between the first and second electronic components becomes easily realized.

The coupling structure of the present invention is preferably arranged such that the second electronic component includes a third substrate that faces the second substrate and that is smaller in terms of surface area than the second substrate, and a distance between the protective film and the third substrate is not more than 2 mm. In the present invention, the larger an area of the protective film in contact with the second substrate is, the more the obtained effect improves. In the arrangement above, the distance between the protective film and the second substrate is short enough. On this account, an area of the protective film being in contact with the second substrate is large enough. This ensures the prevention of the break down of the first wiring, and makes it easy to connect the first and second electronic components.

The coupling structure of the present invention is preferably arranged such that a part of the first wiring is connected to the second wiring, and the protective film is provided above a remaining part of the first wiring, the remaining part not being connected to the second wiring. According to this arrangement, the protective film is provided on a part of the first wiring not being connected to the second wiring, and is not provided on a part of the first wiring being connected to the second wiring. On this account, the electric coupling between the first and second electronic components is easily obtained. Furthermore, it is possible to prevent the break down of a part of the first wiring not being connected to the second wiring.

The coupling structure of the present invention is preferably arranged such that a part of the first wiring is connected to the second wiring, and the protective film has an opening above the part of the first wiring, which is connected to the second wiring. According to this arrangement, the part of the first wiring which is connected to the second wiring is exposed through the opening. Also, the protective film is formed above the remaining part of the first wiring which is not connected to the second wiring. This makes it easy to electrically couple the first electronic component with the second electronic component, and prevents the part of the first wiring, which is not connected to the second wiring, from breaking down.

In the coupling structure of the present invention, the opening is preferably made at an end part of the first substrate. According to this arrangement, the first wiring connected to the second wiring can cover the end part of the first substrate. With this, even if a part of the second electronic component, at which the connection to the first electronic component is made, is small, the first and second electronic components are firmly connected to each other.

In the coupling structure of the present invention, the first substrate is preferably folded so as to wrap up the end part of the second substrate. With this, the size of the first and second electronic component connected to each other can be reduced.

In the coupling structure of the present invention, the protective film is preferably in contact with the side of the end part of the second substrate. According to this arrangement, the protective film is in contact with the side of the end part of the second substrate when the first substrate is folded. On this account, the first wiring on the first substrate is not directly in contact with the side of the end part of the second substrate, so that the break down of the first wiring is prevented.

The coupling structure of the present invention is preferably arranged such that the second electronic component is a panel for a flat display, while the first electronic component is a drive circuit for the flat display. This makes it possible to obtain a highly-reliable flat display in which no break down of the wiring occurs.

The coupling structure of the present invention may be rephrased as a coupling structure of electronic components, for connecting (i) a first electronic component in which first wiring and a protective film for protecting the first wiring are provided on a surface of a first substrate, with (ii) a second electronic component in which second wiring is provided on a surface of a second substrate, the coupling structure being arranged such that, that surface of the first substrate on which the first wiring and the protective film are provided faces that surface of the second substrate on which the second wiring is provided, so that the first wiring and the second wiring are electrically coupled to each other, and a part of the protective film is sandwiched between the first substrate and the second substrate.

The invention being thus described, it will be obvious that the same way may be varied in many ways. Such variations are not to be regarded as a departure from the spirit and scope of the invention.

As described above, the coupling structure of the electronic components of the present invention makes it possible to realize an electronic device in which wiring is not break down and hence reliable. The coupling structure of the present invention is therefore suitably used for a flay display such as a liquid crystal display, which is manufactured by connecting substrates having respective wirings. On this account, the present invention can be suitably applied not only to industries related to flat displays but also industries of manufacturing various types of electronic/electric devices and parts thereof.

Although this invention has been described in its preferred form with a certain degree of particularity, it is understood that the present disclosure of the preferred form has been made only by way of example and that numerous changes in the details of construction and the combination and arrangement of parts may be resorted to without departing from the spirit and the scope of the invention as hereinafter claimed.

1. A coupling structure of electronic components, for connecting (i) a first electronic component in which first wiring and a protective film for protecting the first wiring are provided on a surface of a first substrate, with (ii) a second electronic component in which second wiring is provided on a surface of a second substrate,
wherein,
that surface of the first substrate on which the first wiring and the protective film are provided faces that surface of the second substrate on which the second wiring is provided, so that the first wiring and the second wiring are electrically coupled to each other, and
the protective film is directly in contact with the second substrate.

2. The coupling structure as defined in claim 1, wherein, the first wiring and the second wiring are bonded with each other by an anisotropic conductive adhesive.

3. The coupling structure as defined in claim 1, wherein, the protective film is bonded with the second substrate.

4. The coupling structure as defined in claim 1, wherein, the protective film is 10 μm thick or less.

5. The coupling structure as defined in claim 1, wherein, a part of the protective film, the part being sandwiched between the first substrate and the second substrate, is thinner than a remaining part of the protective film.

6. The coupling structure as defined in claim 1, wherein, the first substrate is flexible.

7. The coupling structure as defined in claim 1, wherein,
the second electronic component includes a third substrate that faces the second substrate and that is smaller in terms of surface area than the second substrate, and
the first substrate is in contact with the third substrate.

8. The coupling structure as defined in claim 1, wherein,
the second electronic component includes a third substrate that faces the second substrate and that is smaller in terms of surface area than the second substrate, and
a distance between the protective film and the third substrate is not more than 2 mm.

9. The coupling structure as defined in claim 1, wherein, a part of the first wiring is connected to the second wiring, and the protective film is provided above a remaining part of the first wiring, the remaining part not being connected to the second wiring.

10. The coupling structure as defined in claim 1, wherein, a part of the first wiring is connected to the second wiring, and the protective film has an opening above the part of the first wiring, which is connected to the second wiring.

11. The coupling structure as defined in claim 10, wherein, the opening is made at an end part of the first substrate.

12. The coupling structure as defined in claim 1, wherein, the first substrate is folded so as to wrap up an end part of the second substrate.

13. The coupling structure as defined in claim 12, wherein, the protective film is in contact with a side face of the end part of the second substrate.

14. The coupling structure as defined in claim 1, wherein, the second electronic component is a panel for a flat display, while the first electronic component is a drive circuit for the flat display.

15. A coupling structure of electronic components, for connecting (i) a first electronic component in which first wiring and a protective film for protecting the first wiring are provided on a surface of a first substrate, with (ii) a second electronic component in which second wiring is provided on a surface of a second substrate,
wherein,
that surface of the first substrate on which the first wiring and the protective film are provided faces that surface of the second substrate on which the second wiring is provided, so that the first wiring and the second wiring are electrically coupled to each other, and
the protective film is in contact with the second substrate, via an adhesive.

16. The coupling structure as defined in claim 15, wherein, a part of the protective film is directly in contact with the second substrate.

17. The coupling structure as defined in claim 16, wherein, the protective film is bonded with the second substrate.

18. The coupling structure as defined in claim 15, wherein, the adhesive includes an anisotropic conductive adhesive.

19. The coupling structure as defined in claim 15, wherein, the first wiring and the second wiring are connected to each other by an anisotropic conductive adhesive.

20. The coupling structure as defined in claim 15, wherein, the protective film is 10 μm thick or less.

21. The coupling structure as defined in claim 15, wherein, a part of the protective film, the part being sandwiched between the first substrate and the second substrate, is thinner than a remaining part of the protective film.

22. The coupling structure as defined in claim 15, wherein, the first substrate is flexible.

23. The coupling structure as defined in claim 15, wherein,
the second electronic component includes a third substrate that faces the second substrate and that is smaller in terms of surface area than the second substrate, and
the first substrate is in contact with the third substrate.

24. The coupling structure as defined in claim 15, wherein,
the second electronic component includes a third substrate that faces the second substrate and that is smaller in terms of surface area than the second substrate, and
a distance between the protective film and the third substrate is not more than 2 mm.

25. The coupling structure as defined in claim 15, wherein, a part of the first wiring is connected to the second wiring, and the protective film is provided above a remaining part of the first wiring, the remaining part not being connected to the second wiring.

26. The coupling structure as defined in claim 15, wherein, a part of the first wiring is connected to the second wiring, and the protective film has an opening above the part of the first wiring, which is connected to the second wiring.

27. The coupling structure as defined in claim 26, wherein, the opening is made at an end part of the first substrate.

28. The coupling structure as defined in claim 25, wherein, the first substrate is folded so as to wrap up an end part of the second substrate.

29. The coupling structure as defined in claim 28, wherein, the protective film is in contact with a side face of the end part of the second substrate.

30. The coupling structure as defined in claim 15, wherein, the second electronic component is a panel for a flat display, while the first electronic component is a drive circuit for the flat display.

31. A coupling structure of electronic components, for connecting (i) a first electronic component in which first wiring and a protective film for protecting the first wiring are provided on a surface of a first substrate, with (ii) a second electronic component in which second wiring is provided on a surface of a second substrate,
wherein,
that surface of the first substrate on which the first wiring and the protective film are provided faces that surface of the second substrate on which the second wiring is provided, so that the first wiring and the second wiring are electrically coupled to each other, and
a part of the protective film is sandwiched between the first substrate and the second substrate.
